(19) United States
(12) Patent Application Publication
(10) Pub. No.: US 2011/0013443 A1
(43) Pub. Date: Jan. 20, 2011

(54) Novel high speed two transistor/two bit NOR read only memory

(75) Inventors: Peter Wung Lee, Saratoga, CA (US); Fu-Chang Hsu, San Jose, CA (US)

Correspondence Address: SAILE ACKERMAN LLC, 28 DAVIS AVENUE, POUGHKEEPSIE, NY, 12603, US

(73) Assignee: Aplus Flash Technology, Inc.

(21) Appl. No.: 12/804,156

(22) Filed: Jul. 15, 2010

Related U.S. Application Data
(60) Provisional application No. 61/271,334, filed on Jul. 20, 2009.

(51) Int. Cl. G11C 17/00; H01L 21/82

(52) U.S. Cl. 365/104; 438/128; 257/E21.602

(57) ABSTRACT

A mask programmable NOR ROM circuit includes serially connected ROM transistors. A drain of a topmost ROM transistor is connected to a bit line and a source of a bottommost ROM transistor is connected to a source line. A source of one ROM transistor is solely connected with a drain of an immediately adjacent ROM transistor. The ROM transistors are programmed by placing a resist mask having openings for selectively modifying a first threshold voltage level of chosen ROM transistors by implanting a threshold voltage modifying impurity. A selected ROM transistor is read by connecting the source line to a sense amplifier circuit and setting the bit line to a read biasing voltage level. The gate of the selected ROM transistor is set to a moderately high read voltage level. The gates of all unselected ROM transistor is set to a very high read voltage level.

This application claims priority under 35 U.S.C. §119 to U.S. Provisional Patent Application Ser. No. 61/271,334, filed Jul. 20, 2009, which is herein incorporated by reference in its entirety.

### BACKGROUND OF THE INVENTION

1. Field of the Invention

This invention relates generally to nonvolatile memory circuits and devices. More particularly, this invention relates to masked programmable read only nonvolatile memory circuits and devices. Even more particularly, this invention relates to circuits and devices incorporating a two transistor/two bit masked programmble read only memory (ROM) cell.

2. Description of Related Art

A system-on-chip (SOC) chip contains a central processing unit (CPU) core, a NVM memory module, a static random access memory (SRAM) and/or dynamic random access memory (DRAM) and a system integrated logic circuits as well as other peripheral modules including a timer, an analog-to-digital converter (ADC) and networking. The SOC chips are essentially a small computer or micro-processing system. Some forms of the systems-on-chip are termed microcontrollers (MCU). More and more microcontrollers with embedded flash memories (flash-MCU) are used in real-time control application markets such as the automobiles. For system designers, they can debug their program code during engineering development by using the flash-MCU. However, there is still a requirement for a lower cost MCU that is accomplished by substituting the flash MCU with a mask programmable ROM MCU. The mask programmable MCE is employed once the system and code have been released for customer use and volume production begins. The cost reduction can be achieved from both testing cost and the memory cell size.

Basically, there are two categories for NOR type ROM cell design. One is a flat contact-less NOR ROM cell. The flat NOR ROM cell provides a contact-less structure by removing an element isolating region from the memory cell array. An example of such flat NOR type memory cell is described in U.S. Pat. No. 5,835,398 (Hirose). The bit lines of the array are composed of an N+ diffusion layer formed in parallel on a P type semiconductor substrate and word-lines of silicide are orthogonally to the bit lines are formed on the bit lines through a gate oxide film. Each transistor which constitutes a memory cell has a source and a drain in a cross portion between the word-lines and the bit lines with a channel being formed in a space portion. The conductivity of the bit lines is low and causes degradation of the performance of the NOR ROM.

The second type of NOR ROM cell is the “non-flat” NOR ROM cell. In this case the bit lines are metal bit lines and each cell is formed with source/drain diffusions having contact to each of the source/drain diffusions to connect to the metal bit lines. The metal bit lines have a much higher conductivity but the individual source/drain diffusions with the contact metallurgy require much more area, thus sacrificing density.

The flat NOR ROM cell has the smallest cell size but the higher resistance of the active bit lines and consequently the lower performance. The “non-flat NOR ROM cell has the largest cell size but the lower resistance of the metal bit lines and consequently higher performance. What is needed is a ROM cell structure that provides high read performance as that provided by the “non-flat” NOR ROM and acceptable memory area approaching that of the flat NOR ROM cell.

### SUMMARY OF THE INVENTION

An object of this invention is to provide a mask programmable NOR ROM cell having two transistors and two bits.

Another object of this invention is to provide a mask programmable NOR ROM device having metal bit lines for increased conductivity and fewer metal contacts for improved density.

To accomplish at least one of these objects, one embodiment of a mask programmable NOR ROM circuit includes a plurality of serially connected ROM transistors. A drain of a topmost ROM transistor is connected to a bit line associated with the plurality of serially connected ROM transistors and a source of a bottommost ROM transistor is connected to a source line associated with the plurality of serially connected ROM transistors. The sources and drains of adjacent ROM transistors of the plurality of serially connected ROM transistors are solely connected with each other.

Each control gate of the plurality of serially connected ROM transistors on each row is commonly connected to a word line. The plurality of serially connected ROM transistors is formed within a well of a first conductivity type (a triple P-type well). The well of the first conductivity type is formed within a deep well of a second conductivity type (Deep N-type well). The deep well of the second conductivity type is formed in a substrate of the first conductivity type (a P-type substrate).

The plurality of serially connected ROM transistors is programmed by is placing a resist mask having openings for selectively modifying a first threshold voltage level of chosen ROM transistors of the plurality of serially connected ROM transistors to a second threshold voltage level. A threshold voltage modifying impurity that is opposite of a first species of the impurity employed in forming the ROM transistor is implanted into the chosen ROM transistors to modify the first threshold voltage level of the chosen ROM transistors to the second threshold voltage level. In some embodiments the threshold voltage modifying impurity is boron. In some embodiments, the first threshold voltage level established by the first species of impurity is from approximately 0.4V to approximately 0.6V (nominally 0.5V). In some embodiments, a lower limit of the second threshold voltage level is approximately a maximum voltage level of the power supply voltage source (VDD). In various embodiments, the lower limit of the second threshold voltage level is approximately 1.8V. In other embodiments, the lower limit of the second threshold voltage level is approximately 3.6V. In some embodiments, an upper limit of the second threshold voltage level is approximately 0.2V greater than the maximum voltage level of the power supply voltage source (VDD).

To read a selected ROM transistor of the plurality of serially connected ROM transistors, the source line is connected to a sense amplifier circuit and has voltage level that is approximately the ground reference voltage level (0.0V). The bit line connected to a selected plurality of serially connected ROM transistors is set to a voltage level of approximately 1.0V. The bit line connected to an unselected plurality of serially connected ROM transistors is set to a voltage level of approximately ground reference voltage level (0.0V). The gate of the selected ROM transistor is set to a moderately high read voltage level that is a lower limit of the second threshold voltage that is the maximum voltage level of the power supply voltage source (VDD) that is approximately 1.8V, in some embodiment or alternately approximately 3.6V, in other embodiments. The gates of all unselected ROM transistors within the plurality of serially connected ROM transistors are set to a very high read voltage level that is approximately 2.0V greater than the upper limit of the second threshold voltage level. If the mask programmable NOR ROM circuit is not selected for reading, the control gates is of all the ROM transistors of the plurality of serially connected ROM transistors is set to the ground reference voltage level (0.0V) to turn off the ROM transistors to block leakage current through the unselected plurality of serially connected ROM transistors. The sense amplifier circuit is a comparator having a reference terminal connected to a reference voltage source.

In another embodiment, a mask programmable NOR ROM device includes an array of a plurality of mask programmable NOR ROM circuits arranged such that the ROM transistors of the mask programmable NOR ROM circuits are configured in rows and columns. Each mask programmable NOR ROM circuit includes a plurality of serially connected ROM transistors on a column. A drain of a topmost ROM transistor of each NOR ROM circuit is connected to a local bit line associated with the column on which each NOR ROM circuit resides. A source of a bottommost ROM transistor of each of the NOR ROM circuits is connected to a local source line associated with the on which each NOR ROM circuit. Each control gate of the ROM transistors on each row is commonly connected to a word line.

The mask programmable NOR ROM device includes a column decode/sense amplifier circuit. The column decode/sense amplifier circuit is connected to provide control signals to local bit lines and the source lines associated with each of the columns of ROM transistors. Each of the local bit lines is connected to one of a plurality of global bit lines through a bit line select transistor and each of the local source lines is connected to one of a plurality of global source lines through a source line select transistor. The global bit lines and the global source lines are connected to the column decode/sense amplifier circuit to transfer the control signals to selected local bit lines and selected local source lines for reading selected ROM transistors within the mask programmable NOR ROM circuits.

The mask programmable NOR ROM device includes a read row decoder. The read row decoder is connected to provide control signals to word lines associated with each of the rows of ROM transistors and the gates of the local bit line select transistors and the source line select transistors connected to each of the local bit lines. The read row decoder transfers the control signals to word lines for reading selected ROM transistors within the mask programmable NOR ROM circuits. The read row decoder also transfers the select control signals to the selected bit line select transistors and the selected source line transistors to transfer the bit line and source line control signals from the column decode/sense amplifier circuit to the selected local bit lines and selected local source lines.

The ROM transistors are programmed by placing a resist mask having openings for selectively modifying a first threshold voltage level of chosen ROM transistors. A threshold voltage modifying impurity that is opposite of a first species of the impurity employed in forming the ROM transistor is implanted into the chosen ROM transistors to modify the first threshold voltage level of the chosen ROM transistors to a second threshold voltage level. In some embodiments the threshold voltage modifying impurity is boron. In some embodiments, the first threshold voltage level established by the first species of impurity is from approximately 0.4V to approximately 0.6V (nominally 0.5V). In some embodiments, a lower limit of the second threshold voltage level is approximately a maximum voltage level of the power supply voltage source (VDD). In various embodiments, the lower limit of the second threshold voltage level is approximately 1.8V. In other embodiments, the lower limit of the second threshold voltage level is approximately 3.6V. In some embodiments, an upper limit of the second threshold voltage level is approximately 0.2V greater than the maximum voltage level of the power supply voltage source (VDD).

To read selected ROM transistors of the plurality of serially connected ROM transistors of a selected NOR ROM circuits, the source lines of the selected NOR ROM circuits are connected to sense amplifier circuits within the column decode/sense amplifier circuit and have a voltage level that is approximately the ground reference to voltage level (0.0V). The bit lines connected to a selected NOR ROM circuits are set to a voltage level of approximately 1.0V. The bit line connected to an unselected NOR ROM circuits are set to a voltage level of approximately ground reference voltage level (0.0V). The gates of the selected ROM transistors are set to a moderately high read voltage level that is a lower limit of the second threshold voltage level. The lower limit of the second threshold voltage level that is the maximum voltage level of the power supply voltage source (VDD) that is approximately 1.8V, in some embodiments or alternately approximately 3.6V, in other embodiments. The gates of all unselected ROM transistors within the selected NOR ROM circuits are set to a very high read voltage level that is approximately 2.0V greater than the upper limit of the second threshold voltage level. In unselected NOR ROM circuits, the control gates of all the ROM transistors of the unselected NOR ROM circuits are set to the ground reference voltage level (0.0V) to turn off the ROM transistors to block leakage current through the unselected NOR ROM circuits. The sense amplifier circuit is a comparator having a reference terminal connected to a reference voltage source.

Further, in various embodiments, a method for forming a mask programmable NOR ROM device begins by providing a substrate onto which an array of a plurality of mask programmable NOR ROM circuits arranged such that the ROM transistors of the NOR ROM circuits are configured in rows and columns. Each NOR ROM circuit is formed by serially connecting the source of a topmost ROM transistor solely with a drain of a bottommost ROM transistor a pair of ROM transistors on a column. In some embodiments, the serially connected source of the topmost ROM transistor circuit and the drain of the bottommost ROM transistor circuit is in fact a single diffusion formed within the surface of the substrate.

A drain of the topmost ROM transistor of each NOR ROM circuit is connected to a local bit line associated with the column on which each NOR ROM circuit resides. A source of the bottommost ROM transistor of each of the NOR ROM circuits is connected to a local source line associated with the on which each NOR ROM circuit. Each control gate of the ROM transistors on each row is commonly connected to a word line.

The method for forming a mask programmable NOR ROM device includes connecting each of the local bit lines to one of a plurality of global bit lines through a bit line select transistor and connecting each of the local source lines is connected to one of a plurality of global source lines through a source line select transistor. A bit line gate control line is connected to each of the gates of the bit line select transistors associated with each of the bit lines. A source line gate control line is connected to each of the gates of the source line select transistors associated with each of the source lines. A word line is connected to each of the gates of the NOR ROM transistors on each row of the array of NOR ROM transistors.

A word line controller within a row read decoder is formed and connected to each of the word lines associated with each row of the NOR ROM transistors. A bit line select controller within the row read decoder is connected to each of the bit line select gates associated with each of the columns of the NOR ROM transistors. A source line select controller within the row read decoder is connected to each of the source line select gates associated with each of the columns of the NOR ROM transistors. A column decode/sense amplifier circuit is formed and connected to provide control signals to local bit lines and the source lines associated with each of the columns of ROM transistors. The global bit lines and the global source lines are connected to the column decode/sense amplifier circuit to transfer the control signals to selected local bit lines and selected local source lines for reading selected ROM transistors within the mask programmable NOR ROM circuits.

The method for forming a mask programmable NOR ROM device includes programming selected ROM transistors by placing a resist mask having openings for selectively modifying a first threshold voltage level of chosen ROM transistors. A threshold voltage modifying impurity that is opposite of a first species of the impurity employed in forming the ROM transistor is implanted into the chosen ROM transistors to modify the first threshold voltage level of the chosen ROM transistors to a second threshold voltage level. In some embodiments the threshold voltage modifying impurity is boron. In some embodiments, the first threshold voltage level established by the first species of impurity is from approximately 0.4V to approximately 0.6V (nominally 0.5V). In some embodiments, a lower limit of the second threshold voltage level is approximately a maximum voltage level of the power supply voltage source (VDD). In various embodiments, the lower limit of the second threshold voltage level is is approximately 1.8V. In other embodiments, the lower limit of the second threshold voltage level is approximately 3.6V. In some embodiments, an upper limit of the second threshold voltage level is approximately 0.2V greater than the maximum voltage level of the power supply voltage source (VDD).

In various embodiments, a method of operating a mask programmable NOR ROM device includes reading selected ROM transistors of the plurality of serially connected ROM transistors of a selected NOR ROM circuits by connecting the source lines of the selected NOR ROM circuits to sense amplifier circuits within the column decode/sense amplifier circuit and have a voltage level that is approximately the ground reference voltage level (0.0V). Setting the bit lines connected to a selected NOR ROM circuits to a moderate read voltage level of approximately 1.0V. Setting the bit lines connected to unselected NOR ROM circuits are set to a voltage level of approximately ground reference voltage level (0.0V). Setting word lines connected to the gates of the selected ROM transistors to a moderately high read voltage level that is a lower limit of the second threshold voltage level. The lower limit of the second threshold voltage level that is the maximum voltage level of the power supply voltage source (VDD) that is approximately 1.8V, in some embodiments or alternately approximately 3.6V, in other embodiments. Setting the gates of all unselected ROM transistors within the selected NOR ROM circuits to a very high read voltage level that is approximately 2.0V greater than the upper limit of the second threshold voltage level. In unselected NOR ROM circuits, setting the control gates of all the ROM transistors of the unselected NOR ROM circuits to the ground reference voltage level (0.0V) to turn off the ROM transistors to block leakage current through the unselected NOR ROM circuits. The sense amplifier circuit is a comparator having a reference terminal connected to a reference voltage source.

### BRIEF DESCRIPTION OF THE DRAWINGS

FIG. 1a is a schematic drawing of a mask programmable NOR ROM circuit.

FIG. 1b is an illustration of a top plan view of an embodiment of a mask programmable NOR ROM circuit.

FIG. 1c is an illustration of a cross-sectional view of an embodiment of a mask programmable NOR ROM circuit.

FIG. 1d is a graph of the threshold voltage level distributions for various embodiments for mask programmable NOR ROM circuits.

FIG. 2 is a block diagram of an embodiment of a mask programmable NOR ROM device.

FIG. 3 is a schematic diagram of another embodiment of a mask programmable NOR ROM array.

FIG. 4 is a chart of operating voltage levels for reading of various embodiments of mask programmable NOR ROM circuits.

FIGS. 5a and 5b are a flowchart of a method for forming an embodiment of a masked programmable NOR ROM.

### DETAILED DESCRIPTION OF THE INVENTION

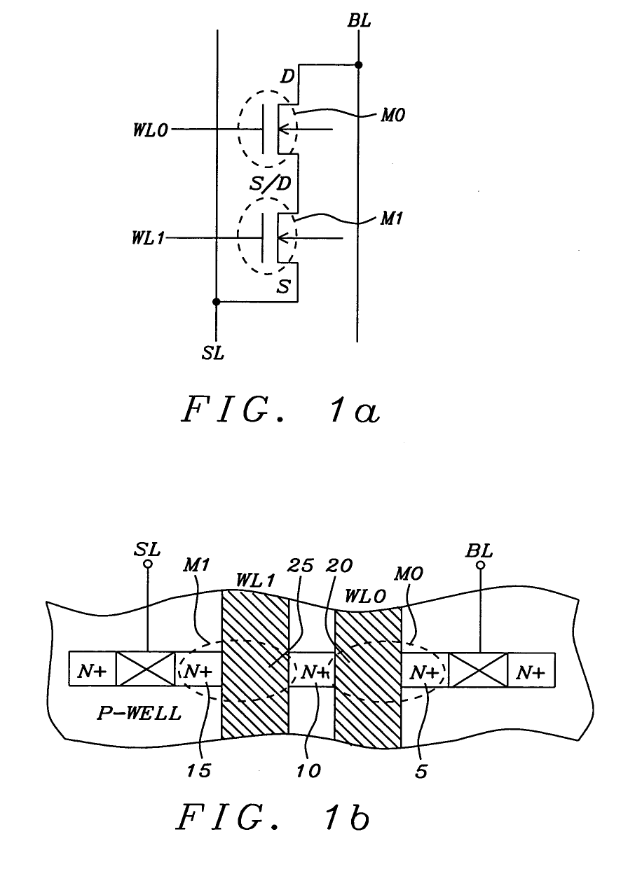

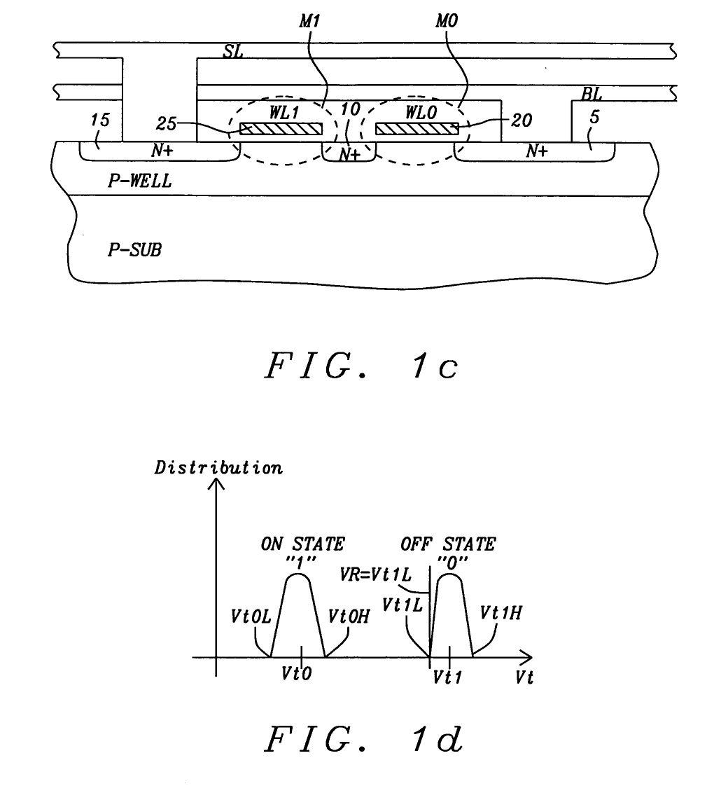

FIG. 1a is a schematic drawing of a mask programmable NOR ROM circuit. FIGS. 1b and 1c are illustrations respectively of a top plan view and of a cross-sectional view of an embodiment of a mask programmable NOR ROM circuit. FIG. 1d is a graph of the threshold voltage level distributions for various embodiments for mask programmable NOR ROM circuits. Referring to FIGS. 1a-1d, one embodiment of a mask programmable NOR ROM circuit includes at least two serially connected ROM transistors M0 and M1. A drain 5 of a topmost ROM transistor M0 is connected to a bit line BL associated with the mask programmable NOR ROM circuit and a source 15 of a bottommost ROM transistor M1 is connected to a source line SL associated with the mask programmable NOR ROM circuit. The source of the topmost ROM transistor M0 and the drain of the bottommost ROM transistor M1 is single diffusion 10 formed within the surface of the P-type well (P-WELL). Each gate 20 and 25 of the serially connected of ROM transistors M0 and M1 is connected respectively to a word line WL0 and WL1. The serially connected ROM transistors M0 and M1 are formed within a P-type well (P-WELL). The P-type well (P-WELL) is formed in a P-type substrate (P-SUB).

The serially connected of ROM transistors M0 and M1 are programmed by placing a resist mask having openings for selectively modifying a first threshold voltage level Vt0 of chosen ROM transistors M0 and M1. A threshold voltage modifying impurity is P-type species that is opposite the species of the impurity (N-type) employed in forming the ROM transistors M0 and M1 is implanted into the chosen ROM transistors M0 and M1 to modify the first threshold voltage level Vt0 of the chosen ROM transistors M0 and M1 to a second threshold voltage level Vt1. In some embodiments the P-type threshold voltage modifying impurity is boron. In some embodiments, the first threshold voltage level Vt0 established by the N-type first species of impurity is from a lower limit Vt0L approximately 0.4V to an upper limit Vt0H of approximately 0.6V (nominally 0.5V). In some embodiments, a lower limit Vt1L of the second threshold voltage level is approximately a maximum voltage level of the power supply voltage source (VDD). In various embodiments, the lower limit Vt1L of the second threshold voltage level Vt1 is approximately 1.8V. In other embodiments, the lower limit Vt1L of the second threshold voltage Vt1 level is approximately 3.6V. In some embodiments, an upper limit Vt1H of the second threshold voltage level Vt1 is approximately 0.2V greater than the maximum voltage level of the power supply voltage source (VDD).

To read a selected ROM transistor M0 or M1, the source line SL is connected to a sense amplifier circuit (not shown) and has voltage level that is approximately the ground reference voltage level (0.0V). The bit line BL connected to a selected serially connected of ROM transistors M0 and M1 is set to a voltage level of approximately 1.0V. The bit line BL connected to an unselected serially connected of ROM transistor M0 or M1 is set to a voltage level of approximately ground reference voltage level (0.0V). The gate of the selected ROM transistor M0 or M1 is set to a moderately high read voltage level through a word line WL0 or WL1. The moderately high read voltage level is the lower limit of the second threshold voltage Vt1L that is the maximum voltage level of the power supply voltage source (VDD) that is approximately 1.8V, in some embodiments, or alternately approximately 3.6V, in other embodiments. The gates of all unselected ROM transistor M0 or M1 is set to a very high read voltage level through a word line WL0 or WL1. The very high read voltage level through a word line WL0 or WL1 is approximately 2.0V greater than the upper limit Vt1H of the second threshold voltage level VT1. If the mask programmable NOR ROM circuit is not selected for reading, the gates of all the ROM transistors M0 and M1 are set to the ground reference voltage level (0.0V) through a word line WL0 or WL1. This turns off the ROM transistors M0 and M1 to block leakage current through the unselected serially connected of ROM transistors M0 and M1.

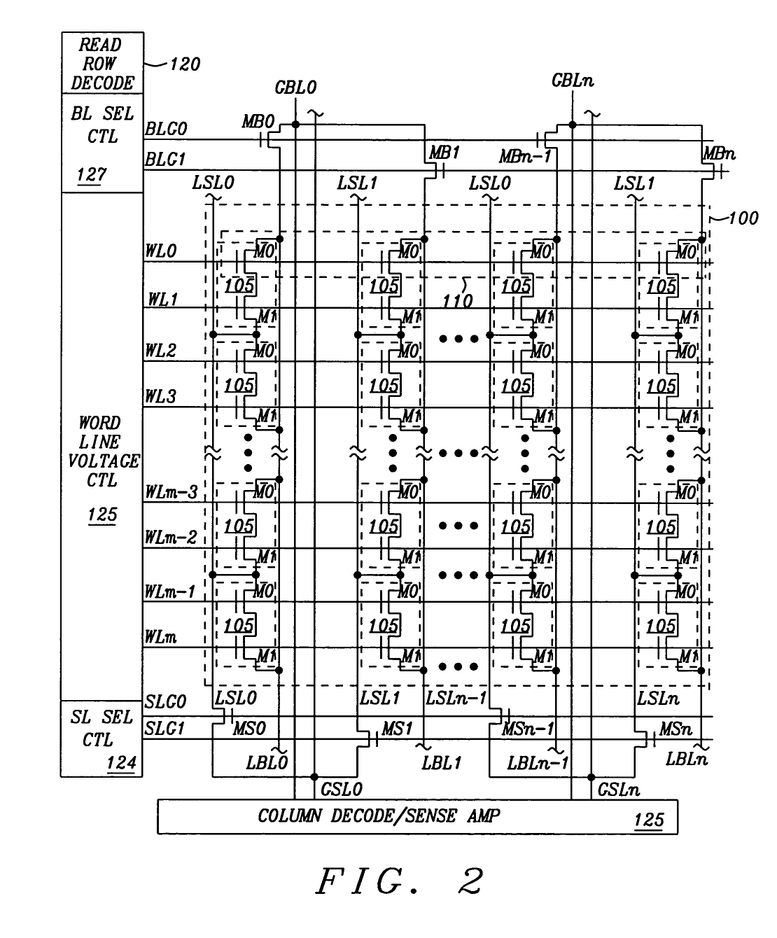

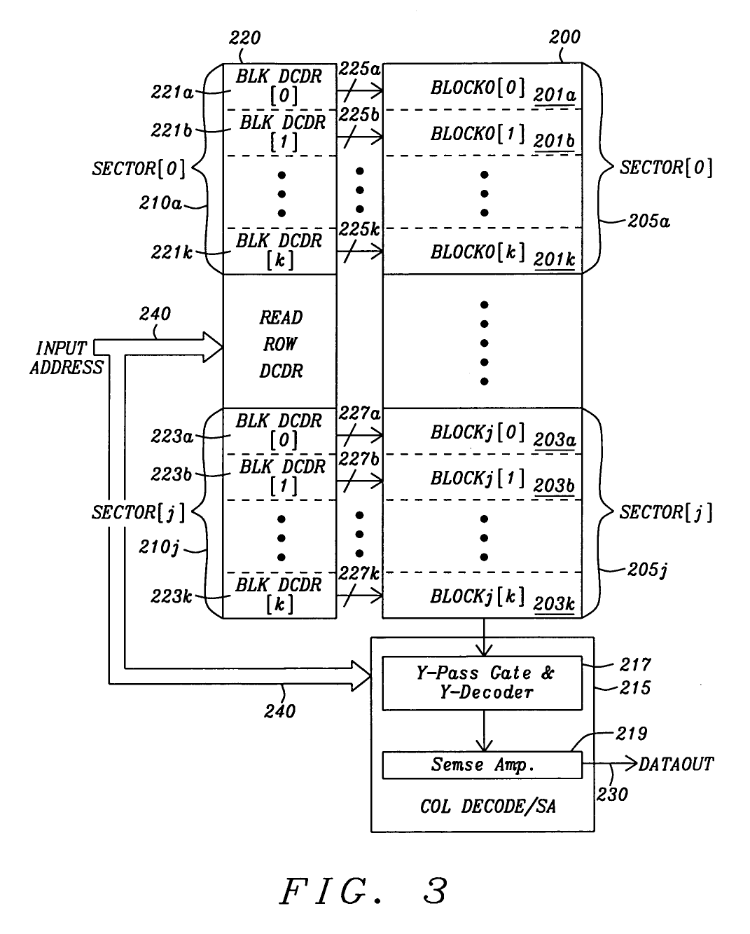

FIG. 2 is a block diagram of an embodiment of a mask programmable NOR ROM device. The mask programmable NOR ROM device includes an array 100 of two transistor mask programmable NOR ROM circuits 105 arranged in a matrix of rows and columns. Each of the two transistor mask programmable NOR ROM circuits 105 includes two mask programmable NOR ROM transistors M0 and M1. The two mask programmable NOR ROM transistors M0 and M1 are structured and operate as the mask programmable NOR ROM transistors M0 and M1 of FIGS. 1a-1g. The drain of the ROM transistor M0 is connected to one of the local bit lines LBL0, . . . , LBLn. The source of the ROM transistor M1 is connected to one of the local source lines LSL0, . . . , LSLn. The source of the ROM transistor M0 is connected to the drain of ROM transistors M1.

The local bit lines LBL0, . . . , LBLn associated with adjacent columns of the two transistor mask programmable NOR ROM circuit 105 are connected through the bit lines select transistors MB0, . . . , MBn to the global bit lines GBL0, . . . , GBLn. In the embodiment shown, each of the global bit lines GBL0, . . . , GBLn are connected to a pair of the local bit lines LBL0, . . . , LBLn through the bit lines select transistors MB0, . . . , MBn. However, in other embodiments, each of the global bit lines GBL0, . . . , GBLn are connected to multiple local bit lines LBL0, . . . , LBLn through the bit lines select transistors MB0, . . . , MBn. The local source lines LSL0, . . . , LSLn associated with adjacent columns of the two transistor mask programmable NOR ROM circuit 105 are connected through the source lines select transistors MS0, . . . , MS1 to the global source lines GSL0, . . . , GSLn. In the embodiment shown, each of the global source lines GSL0, . . . , GSLn are connected to a pair of the local source lines LSL0, . . . , LSLn through the source lines select transistors MS0, . . . , MSn. However, in other embodiments, each of the global source lines GSL0, . . . , GSLn are connected to multiple local source lines LSL0, . . . , LSLn through the source lines select transistors MS0, . . . , MSn. The global bit lines GBL0, . . . , GBLn and the global source lines 540a, . . . , 540n are connected to the column decode and sense amplifier circuit 125. The column decode and sense amplifier circuit 125 generates the appropriate voltage levels for selectively reading the two transistor two transistor mask programmable NOR ROM circuits 105.

Each of the gates of the mask programmable NOR ROM transistors M0 and M1 of the two transistor mask programmable NOR ROM circuits 105 on each row of the array 100 is connected to one of the word lines WL0, . . . , WLm. The word lines WL0, . . . , WLm are connected to the word line voltage control sub-circuit 123 in the read row decoder 120.

Each of the gates of the bit lines select transistors MB0, . . . , MBn are connected to one of the bit line gating signal line BL0 or BLG1 that is connected to the bit line select control sub-circuit 122 within the read row decoder 120 to provide the select signals for activation of the bit lines select transistors MB0, . . . , MBn to connect a selected local bit lines LBL0, . . . , LBLn to its associated global bit line GSL0, . . . , GSLn. Each of the gates of the source lines select transistors MS0, . . . , MSn are connected to one of the bit line gating signal line BLG0 or BLG1 that is connected to the source line select control circuit 124 within the read row decoder 120 to connect the local source lines LSL0, . . . , LSLn to their associated global source lines GSL0, . . . , GSLn. The source line voltage control circuit 124 provides the select signals for activation of the source lines select transistors MS0, . . . , MSn to connect a selected local source lines LSL0, . . . , LSLn to its associated global source line GSL0, . . . , GSLn.

The array 100 of the mask programmable NOR ROM device, in some embodiments, is considered to be a block sub-array of a larger array. Each row of the array 100 of the mask programmable NOR ROM transistors M0 and M1 is designated as a page of the array. FIG. 3 is a schematic diagram of another embodiment of a mask programmable NOR ROM array 200. The mask programmable NOR ROM array 200 includes multiple blocks 201a, . . . , 201k, . . . , 203a, . . . , 203k wherein each of the of the blocks 201a, . . . , 201k, . . . , 203a, . . . , 203k is the array 100 of the mask programmable NOR ROM devices as described in FIG. 2. Groups of the blocks 201a, . . . , 201k, . . . , 203a, . . . , 203k are collected into sectors 205a, . . . , 205j.

The column decoder/sense amplifier 215 includes a Y-Pass gate and Y-decoder 217 to select and connect the selected global bit lines and global source lines (as shown in FIG. 2) to sense amplifiers 219 to sense and condition the data state of selected ROM transistors M0 or M1 of the selected blocks 201a, . . . , 201k, . . . , 203a, . . . , 203k to provide the output data 230 to external circuitry. The input address 240 is decoded to select the desired columns of the ROM transistors M0 and M1 for reading.

The read row decoder 220 includes block row decoders 221a, . . . , 221k, . . . , 223a, . . . , 223k. The block row decoders 221a, . . . , 221k, . . . , 223a, . . . , 223k are the read row decoder 120 of FIG. 2. Groups of the block row decoders 221a, . . . , 221k, . . . , 223a, . . . , 223k are collected together to form the sector row decoders 210a, . . . , 210j. The input address 240 is decoded to the sector level to select the sector row decoders 210a, . . . , 210j. The input address 240 is further decoded to select the block row decoders 221a, . . . , 221k, . . . , 223a, . . . , 223k. The input address 240 is further decoded by the block row decoders 221a, . . . , 221k, . . . , 223a, . . . , 223k to select the page of the ROM transistors for reading.

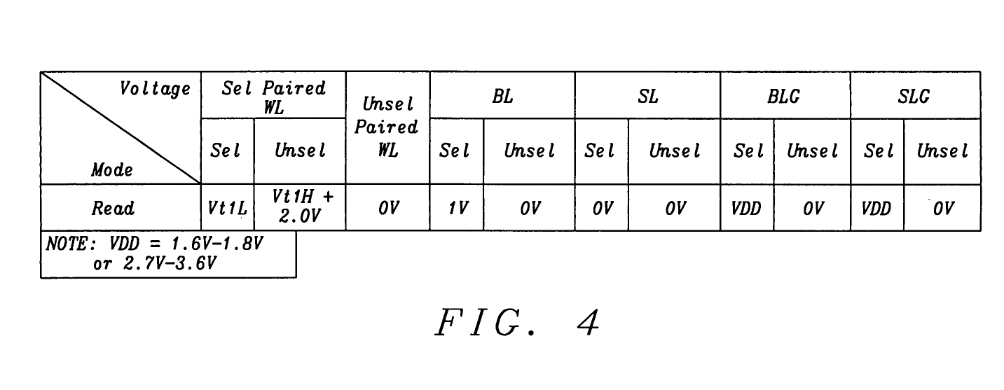

FIG. 4 is a chart of operating voltage levels for reading of various embodiments of mask programmable NOR ROM circuits. Refer now to FIGS. 2 and 4 for a discussion of a method of operation of a mask programmable NOR ROM array 100. In this discussion, the page 110 is selected to be read while all other rows of the mask programmable NOR ROM array 100 are not being read. The source line select is control circuit 124 is activated to set the selected source line gating signal line SLG0 or SLG1 to the source line gating voltage to turn on the source line select transistors MS0, . . . , MSn connect the local source lines LSL0, . . . , LSLn to the associated global source lines GSL0, . . . , GSLn of the selected NOR ROM circuits and thus to the sense amplifier circuits within the column decode/sense amplifier circuit 125. The source line gating voltage is approximately the voltage level of the power supply voltage source VDD. The selected and unselected global source lines GSL0, . . . , GSLn and thus the local source lines LSL0, . . . , LSLn have a voltage level that is approximately the ground reference voltage level (0.0V).

The bit line select control sub-circuit 122 is activated to set the selected bit line gating signal line BLG0 or BLG1 to the bit line gating voltage to turn on the bit line select transistors MB0, . . . , MBn connect the local bit lines LBL0, . . . , LBLn to the associated global bit lines GBL0, . . . , GBLn of the selected NOR ROM circuits. The column decode/sense amplifier circuit 125 sets the selected global bit lines GBL0, . . . , GBLn and thus the local bit lines LBL0, . . . , LBLn to the moderate read voltage level. The bit line gating voltage is approximately the voltage level of the power supply voltage bit VDD. The moderate read voltage level is approximately the 1.0V. The unselected global bit lines GBL0, . . . , GBLn bit lines and thus the unselected local bit lines LBL0, . . . , LBLn are set to a voltage level that is approximately the ground reference voltage level. (0.0V).

The word line voltage control sub-circuit 123 sets the selected word lines WL0, . . . , WLm connected to the gates of the selected ROM transistors to a moderately high read voltage level. The moderately high read voltage level is a lower limit of the second threshold voltage level Vt1L. The lower limit of the second threshold voltage level Vt1L is the maximum voltage level of the power supply voltage source (VDD) that is approximately 1.8V, in some embodiments or alternately approximately 3.6V, in other embodiments. The word line voltage control sub-circuit 123 sets the word lines WL0, . . . , WLm connected to the gates of all unselected ROM transistors within the selected NOR ROM circuits to a very high read voltage level that is approximately 2.0V greater than the upper limit of the second threshold voltage level Vt1H. In the rows of the unselected NOR ROM circuits, the word line voltage control sub-circuit 123 sets the word lines WL0, . . . , WLm connected to the control gates of all the ROM transistors of the unselected NOR ROM circuits to the ground reference voltage level (0.0V) to turn off the mask programmable NOR ROM transistors M0 and M1 to block leakage current through the unselected NOR ROM circuits.

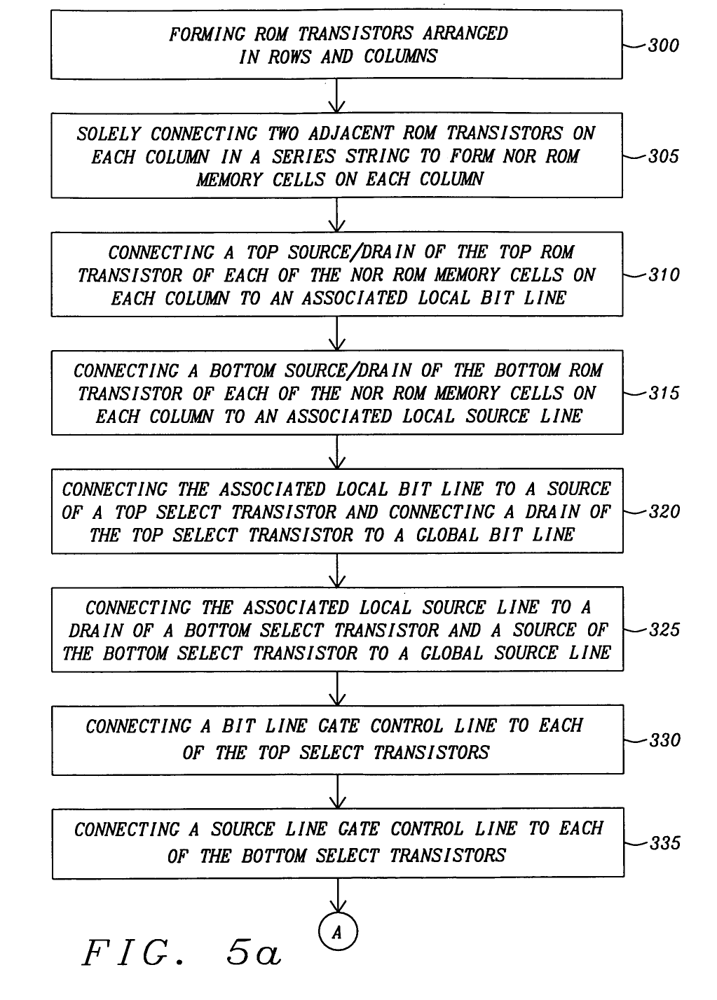

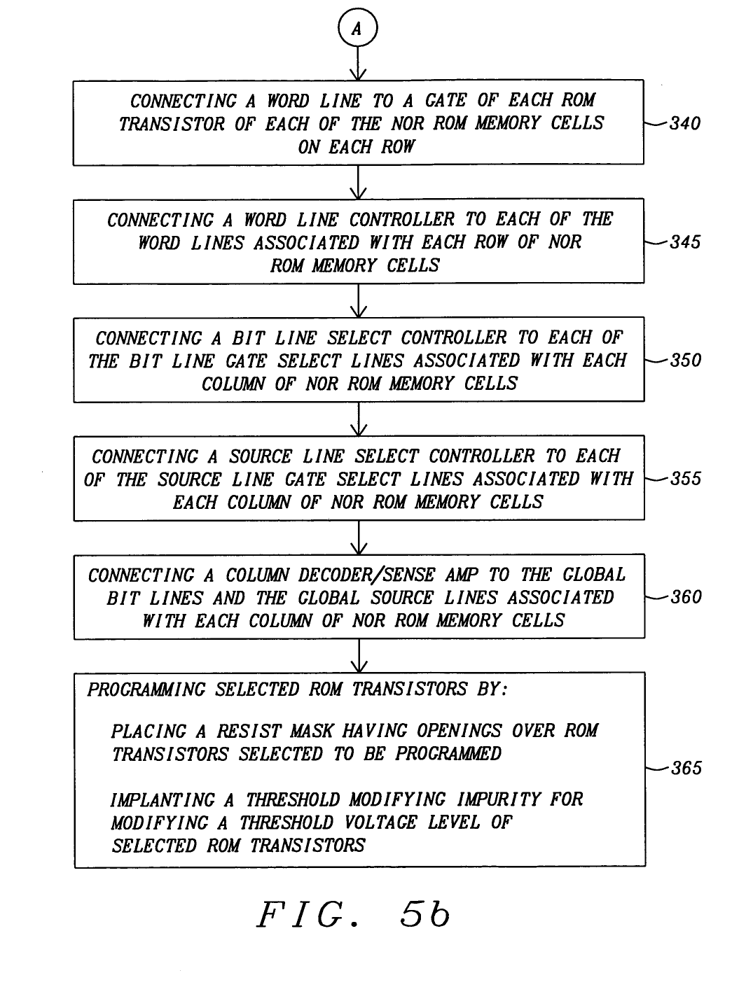

FIGS. 5a and 5b are a flowchart of a method for forming an embodiment of a masked programmable NOR ROM. Referring now to FIGS. 5a and 5b, a method for forming a mask programmable NOR ROM device begins by providing (Box 300) a substrate onto which an array of a plurality of mask programmable NOR ROM circuits arranged such that the ROM transistors of the NOR ROM circuits are configured in rows and columns. Each NOR ROM circuit is formed by serially connecting (Box 305) the source of a topmost ROM transistor solely with a drain of a bottommost ROM transistor a pair of ROM transistors on a column. In some embodiments, the serially connected source of the topmost ROM transistor circuit and the drain of the bottommost ROM transistor circuit is in fact a single diffusion 10 formed within the surface of the substrate as shown in FIGS. 1b and 1c.

A drain of the topmost ROM transistor of each NOR ROM circuit is connected (Box 310) to a local bit line associated with the column on which each NOR ROM circuit resides. A source of the bottommost ROM transistor of each of the NOR ROM circuits is connected (Box 315) to a local source line associated with the column on which each NOR ROM circuit resides. Each control gate of the ROM transistors on each row is commonly connected to a word line.

The method for forming a mask programmable NOR ROM device includes connecting (Box 320) each of the local bit lines to one of a plurality of global bit lines through a bit line select transistor and connecting (Box 325) each of the local source lines is connected to one of a plurality of global source lines through a source line select transistor. A bit line gate control line is connected (Box 330) to each of the gates of the bit line select transistors associated with each of the bit lines. A source line gate control line is connected (Box 335) to each of the gates of the source line select transistors associated with each of the source lines. A word line is connected (Box 340) to each of is the gates of the NOR ROM transistors on each row of the array of NOR ROM transistors.

A word line controller within a row read decoder is formed and connected (Box 345) to each of the word lines associated with each row of the NOR ROM transistors. A bit line select controller within the row read decoder is connected (Box 350) to each of the bit line select gates associated with each of the columns of the NOR ROM transistors. A source line select controller within the row read decoder is connected (Box 355) to each of the source line select gates associated with each of the columns of the NOR ROM transistors. A column decode/sense amplifier circuit is formed and connected (Box 360) to provide control signals to local bit lines and the source lines associated with each of the columns of ROM transistors. The global bit lines and the global source lines are connected to the column decode/sense amplifier circuit to transfer the control signals to selected local bit lines and selected local source lines for reading selected ROM transistors within the mask programmable NOR ROM circuits.

The method for forming a mask programmable NOR ROM device includes programming (Box 365) selected ROM transistors by placing a resist mask having openings for selectively modifying a first threshold voltage level of chosen ROM transistors. A threshold voltage modifying impurity that is opposite of a first species of the impurity employed in forming the ROM transistor is implanted into the chosen ROM transistors to modify the first threshold voltage level of the chosen ROM transistors to a second threshold voltage level. In some embodiments the threshold voltage modifying impurity is boron. In some embodiments, the first threshold voltage level established by the first species of impurity is from approximately 0.4V to approximately 0.6V (nominally 0.5V). In some embodiments, a lower limit of the second threshold voltage level is approximately a maximum voltage level of the power supply voltage source (VDD). In various embodiments, the lower limit of the second threshold voltage level is approximately 1.8V. In other embodiments, the lower limit of the second threshold voltage level is approximately 3.6V. In some embodiments, an upper limit of the second is threshold voltage level is approximately 0.2V greater than the maximum voltage level of the power supply voltage source (VDD).

While the embodiments describe mask programmable NOR ROM circuits with a pair of ROM transistors, it is in keeping with the intent of this invention that, in other embodiments, mask programmable ROM circuits include multiple serially connected ROM transistors. The drain, as described above, of the topmost ROM transistors is connected to a local bit line and the source of the bottommost ROM transistors is connected to a local source line. In these embodiments, the source of one transistor is connected to the drain of an immediately adjacent ROM transistor.

These embodiments are not as desirable since the additional ROM transistors added to the mask programmable NOR ROM circuits degrade the overall performance of the mask programmable NOR ROM circuits.

While this invention has been particularly shown and described with reference to the preferred embodiments thereof, it will be understood by those skilled in the art that various changes in form and details may be made without departing from the spirit and scope of the invention.

The invention claimed is:

1. A mask programmable NOR ROM circuit comprising:
a plurality of serially connected ROM transistors;
wherein a drain of a topmost ROM transistor is connected to a bit line associated with the plurality of serially connected ROM transistors;
wherein a source of a bottommost ROM transistor is connected to a source line associated with the plurality of serially connected ROM transistors; and
wherein a source of one ROM transistor is solely connected with a drain of an immediately adjacent ROM transistor of the plurality of serially connected ROM transistors.

2. The mask programmable NOR ROM circuit of claim 1 wherein each control gate of the plurality of serially connected ROM transistors on each row is commonly connected to a word line.

3. The mask programmable NOR ROM circuit of claim 1 wherein the plurality of serially connected ROM transistors is formed within a well of a first conductivity type.

4. The mask programmable NOR ROM circuit of claim 3 wherein the well of the first conductivity type is formed within a deep well of a second conductivity type.

5. The mask programmable NOR ROM circuit of claim 3 wherein the deep well of the second conductivity type is formed in a substrate of the first conductivity type.

6. The mask programmable NOR ROM circuit of claim 1 wherein the plurality of serially connected ROM transistors is programmed by placing a resist mask having openings for selectively modifying a first threshold voltage level of chosen ROM transistors of the plurality of serially connected ROM transistors.

7. The mask programmable NOR ROM circuit of claim 6 wherein a threshold voltage modifying impurity that is opposite of a first species of the impurity employed in forming the ROM transistors is implanted into the chosen ROM transistors to modify the first threshold voltage level of the chosen ROM transistors to a second threshold voltage level.

8. The mask programmable NOR ROM circuit of claim 7 wherein the threshold voltage modifying impurity is boron.

9. The mask programmable NOR ROM circuit of claim 7 wherein the first threshold voltage level established by the first species of impurity is from approximately 0.4V to approximately 0.6V (nominally 0.5V).

10. The mask programmable NOR ROM circuit of claim 9 wherein a lower limit of the second threshold voltage level is approximately a maximum voltage level of the power supply voltage source (VDD).

11. The mask programmable NOR ROM circuit of claim 10 wherein the lower limit of the second threshold voltage level is approximately 1.8V.

12. The mask programmable NOR ROM circuit of claim 10 wherein the lower limit of the second threshold voltage level is approximately 3.6V.

13. The mask programmable NOR ROM circuit of claim 10 wherein an upper limit of the second threshold voltage level is approximately 0.2V greater than the maximum voltage level of the power supply voltage source.

14. The mask programmable NOR ROM circuit of claim 1 wherein reading a selected ROM transistor of the plurality of serially connected ROM transistors is performed by:
connecting the source line to a sense amplifier circuit; and
setting the source line to a voltage level that is approximately the ground reference voltage level;
setting the bit line to a voltage level of approximately 1.0V;
setting the gate of the selected ROM transistor to a moderately high read voltage level;
setting the gates of all unselected ROM transistors within the plurality of serially connected ROM transistors to a very high read voltage level.

15. The mask programmable NOR ROM circuit of claim 1 wherein the moderately high read voltage level is a lower limit of the second threshold voltage.

16. The mask programmable NOR ROM circuit of claim 1 wherein the lower limit of the second threshold voltage is the maximum voltage level of the power supply voltage source.

17. The mask programmable NOR ROM circuit of claim 16 wherein the power supply voltage source is approximately 1.8V or approximately 3.6V.

18. The mask programmable NOR ROM circuit of claim 1 wherein the bit line connected to an unselected plurality of serially connected ROM transistors is set to a voltage level of approximately ground reference voltage level.

19. The mask programmable NOR ROM circuit of claim 18 wherein if the mask programmable NOR ROM circuit is not selected for reading, the control gates of all the ROM transistors of the plurality of serially connected ROM transistors is set to the ground reference voltage level to turn off the ROM transistors to block leakage current through the unselected plurality of serially connected ROM transistors.

20. A mask programmable NOR ROM device comprising:
an array of a plurality of mask programmable NOR ROM circuits arranged such that the ROM transistors of the mask programmable NOR ROM circuits are configured in rows and columns, each mask programmable NOR ROM circuit comprising:
a plurality of serially connected ROM transistors;
wherein a drain of a topmost ROM transistor is connected to a bit line associated with the plurality of serially connected ROM transistors;
wherein a source of a bottommost ROM transistor is connected to a source line associated with the plurality of serially connected ROM transistors;
wherein a source of one ROM transistor is solely connected with a drain of an immediately adjacent ROM transistor of the plurality of serially connected ROM transistors;
a plurality of bit lines, each bit line associated with one column of the array of the plurality of mask programmable NOR ROM circuits;
a plurality of source lines, each source line associated with one column of the array of the plurality of mask programmable NOR ROM circuits; and
a plurality of word lines, each word line associated with one row of the array of the plurality of mask programmable NOR ROM circuits.

21. The mask programmable NOR ROM device of claim 20 wherein each control gate of the plurality of serially connected ROM transistors on each row is commonly connected to a word line.

22. The mask programmable NOR ROM device of claim 20 wherein the plurality of serially connected ROM transistors is formed within a well of a first conductivity type.

23. The mask programmable NOR ROM device of claim 22 wherein the well of the first conductivity type is formed within a deep well of a second conductivity type.

24. The mask programmable NOR ROM device of claim 22 wherein the deep well of the second conductivity type is formed in a substrate of the first conductivity type.

25. The mask programmable NOR ROM device of claim 20 wherein the plurality of serially connected ROM transistors is programmed by placing a resist mask having openings for selectively modifying a first threshold voltage level of chosen ROM transistors of the plurality of serially connected ROM transistors.

26. The mask programmable NOR ROM device of claim 25 wherein a threshold voltage modifying impurity that is opposite of a first species of the impurity employed in forming the ROM transistors is implanted into the chosen ROM transistors to modify the first threshold voltage level of the chosen ROM transistors to a second threshold voltage level.

27. The mask programmable NOR ROM device of claim 26 wherein the threshold voltage modifying impurity is boron.

28. The mask programmable NOR ROM device of claim 26 wherein the first threshold voltage level established by the first species of impurity is from approximately 0.4V to approximately 0.6V (nominally 0.5V).

29. The mask programmable NOR ROM device of claim 28 wherein a lower limit of the second threshold voltage level is approximately a maximum voltage level of the power supply voltage source (VDD).

30. The mask programmable NOR ROM device of claim 29 wherein the lower limit of the second threshold voltage level is approximately 1.8V.

31. The mask programmable NOR ROM device of claim 29 wherein the lower limit of the second threshold voltage level is approximately 3.6V.

32. The mask programmable NOR ROM device of claim 29 wherein an upper limit of the second threshold voltage level is approximately 0.2V greater than the maximum voltage level of the power supply voltage source.

33. The mask programmable NOR ROM device of claim 20 further comprises:
a column decode/sense amplifier circuit to provide control signals to local bit lines and the source lines associated with each of the columns of ROM transistors.

34. The mask programmable NOR ROM device of claim 33 further comprising a plurality of bit line select transistors, wherein each of the local bit lines is connected to one of a plurality of global bit lines through one bit line select transistor.

35. The mask programmable NOR ROM device of claim 34 further comprising a plurality of source line select transistors, wherein each of the local source lines is connected to one of a plurality of source bit lines through one source line select transistor.

36. The mask programmable NOR ROM device of claim 35 wherein the global bit lines and the global source lines are connected to the column decode/sense amplifier circuit to transfer the control signals to selected local bit lines and selected local source lines for reading selected ROM transistors within the mask programmable NOR ROM circuits.

37. The mask programmable NOR ROM device of claim 20 further comprising a read row decoder connected to provide control signals to word lines associated with each of the rows of ROM transistors, the gates of the local bit line select transistors, and gates of the source line select transistors connected to each of the local bit lines for reading selected ROM transistors within the mask programmable NOR ROM circuits.

38. The mask programmable NOR ROM device of claim 20 wherein selected ROM transistors are programmed by placing a resist mask having openings for selectively modifying a first threshold voltage level of selected ROM transistors of the array of a plurality of mask programmable NOR ROM circuits.

39. The mask programmable NOR ROM device of claim 38 wherein a threshold voltage modifying impurity that is opposite of a first species of the impurity employed in forming the ROM transistors is implanted into the chosen ROM transistors to modify the first threshold voltage level of the chosen ROM transistors to a second threshold voltage level.

40. The mask programmable NOR ROM device of claim 39 wherein the threshold voltage modifying impurity is boron.

41. The mask programmable NOR ROM device of claim 39 wherein the first threshold voltage level established by the first species of impurity is from approximately 0.4V to approximately 0.6V (nominally 0.5V).

42. The mask programmable NOR ROM device of claim 41 wherein a lower limit of the second threshold voltage level is approximately a maximum voltage level of the power supply voltage source (VDD).

43. The mask programmable NOR ROM device of claim 42 wherein the lower limit of the second threshold voltage level is approximately 1.8V.

44. The mask programmable NOR ROM device of claim 42 wherein the lower limit of the second threshold voltage level is approximately 3.6V.

45. The mask programmable NOR ROM device of claim 42 wherein an upper limit of the second threshold voltage level is approximately 0.2V greater than the maximum voltage level of the power supply voltage source.

46. The mask programmable NOR ROM device of claim 20 wherein reading selected ROM transistors of array of a plurality of mask programmable NOR ROM circuits is performed by:
connecting the source line to a sense amplifier circuit and has voltage level that is approximately the ground reference voltage level;
setting the bit line to a voltage level of approximately 1.0V;
setting the gate of the selected ROM transistor to a moderately high read voltage level;
setting the gates of all unselected ROM transistors within the plurality of serially connected ROM transistors to a very high read voltage level.

47. The mask programmable NOR ROM device of claim 46 wherein the moderately high read voltage level is a lower limit of the second threshold voltage.

48. The mask programmable NOR ROM device of claim 46 wherein the lower limit of the second threshold voltage is the maximum voltage level of the power supply voltage source.

49. The mask programmable NOR ROM device of claim 46 wherein the power supply voltage source is approximately 1.8V or approximately 3.6V.

50. The mask programmable NOR ROM device of claim 46 wherein the bit line connected to an unselected plurality of serially connected ROM transistors is set to a voltage level of approximately ground reference voltage level.

51. The mask programmable NOR ROM device of claim 50 wherein if the mask programmable NOR ROM circuit is not selected for reading, the control gates of all the ROM transistors of the plurality of serially connected ROM transistors is set to the ground reference voltage level to turn off the ROM transistors to block leakage current through the unselected plurality of serially connected ROM transistors.

52. A method for forming a mask programmable NOR ROM device comprising:
providing a substrate;
forming an array of a plurality of mask programmable NOR ROM circuits on the substrate, wherein each mask programmable NOR ROM circuit comprises a plurality of ROM transistors;
arranging the ROM transistors of the NOR ROM circuits in rows and columns:
forming each NOR ROM circuit by:
connecting a drain of a topmost ROM transistor to a bit line associated with the plurality of serially connected ROM transistors;
connecting a source of a bottommost ROM transistor to a source line associated with the plurality of serially connected ROM transistors;
solely connecting a source of one ROM transistor with a drain of an immediately adjacent ROM transistor of the plurality of serially connected ROM transistors.

53. The method of claim 52 wherein solely connecting a source of one ROM transistor with a drain of an immediately adjacent ROM transistor of the plurality of serially connected ROM transistors comprises forming a single diffusion for the source of the topmost ROM transistor and the drain of the bottommost transistor within the surface of the substrate.

54. The method of claim 52 further comprising connecting a drain of the topmost ROM Transistor to a local bit line associated with the column on which each NOR ROM circuit resides.

55. The method of claim 54 further comprising connecting a source of the bottommost ROM Transistor to a local source line associated with the column on which each NOR ROM circuit resides.

56. The method of claim 55 further comprising connecting commonly each control gate of the ROM transistors on each row to a word line.

57. The method of claim 56 further comprising connecting each of the local bit lines to one of a plurality of global bit lines through a bit line select transistor.

58. The method of claim 57 further comprising connecting each of the local source lines is connected to one of a plurality of global source lines through a source line select transistor.

59. The method of claim 58 further comprising connecting a bit line gate control line to each of the gates of the bit line select transistors associated with each of the bit lines.

60. The method of claim 59 further comprising connecting a source line gate control line to each of the gates of the source line select transistors associated with each of the source lines.

61. The method of claim 60 further comprising connecting a word line to each of the gates of the NOR ROM transistors on each row of the array of NOR ROM transistors.

62. The method of claim 61 further comprising forming a row read decoder wherein forming the row read decoder comprises:
forming a word line controller;
connecting the word line controller to each of the word lines associated with each row of the NOR ROM transistors;
forming a bit line select controller;
connecting the bit line select controller to each of the bit line select gates associated with each of the columns of the NOR ROM transistors;
forming a source line select controller;
connecting the source line select controller to each of the source line select gates associated with each of the columns of the NOR ROM transistors.

63. The method of claim 62 further comprising:
forming a column decode/sense amplifier circuit; and
connecting the column decode/sense amplifier to provide control signals to global bit lines and the global source lines associated with each of the columns of ROM transistors;
connecting the global bit lines to bit line select transistors and the global source lines to local source line select transistors to selectively transfer the control signals to selected local bit lines and selected local source lines for reading selected ROM transistors within the mask programmable NOR ROM circuits.

64. The method of claim 55 further comprising programming selected ROM transistors by placing a resist mask having openings for selectively modifying a first threshold voltage level of chosen ROM transistors.

65. The method of claim 64 further comprising implanting a threshold voltage modifying impurity that is opposite of a first species of the impurity employed in forming the ROM transistor into the chosen ROM transistors to modify the first threshold voltage level of the chosen ROM transistors to a second threshold voltage level.

66. The method of claim 65 wherein the threshold voltage modifying impurity is boron.

67. The method of claim 65 wherein the first threshold voltage level established by the first species of impurity is from approximately 0.4V to approximately 0.6V.

68. The method of claim 65 wherein a lower limit of the second threshold voltage level is approximately a maximum voltage level of the power supply voltage source (VDD).

69. The method of claim 68 wherein the lower limit of the second threshold voltage level is approximately 1.8V.

70. The method of claim 68 wherein the lower limit of the second threshold voltage level is approximately 3.6V.

71. The method of claim 65 wherein an upper limit of the second threshold voltage level is approximately 0.2V greater than the maximum voltage level of the power supply voltage source.

72. A method of operating a mask programmable NOR ROM device reading a selected ROM transistor of the plurality of serially connected ROM transistors is performed by:
connecting the source line to a sense amplifier circuit and setting a voltage level of the source line to approximately the ground reference voltage level;
setting the bit line to a voltage level of approximately 1.0V;
setting the gate of the selected ROM transistor to a moderately high read voltage level;
setting the gates of all unselected ROM transistors within the plurality of serially connected ROM transistors to a very high read voltage level; and
sensing by the sense amplifier circuit a voltage state of the selected ROM transistors.

73. The mask programmable NOR ROM circuit of claim 72 wherein the moderately high read voltage level is a lower limit of the second threshold voltage.

74. The method of operating a mask programmable NOR ROM device of claim 73 wherein the lower limit of the second threshold voltage is the maximum voltage level of the power supply voltage source.

75. The method of operating a mask programmable NOR ROM device of claim 74 wherein the power supply voltage source is approximately 1.8V or approximately 3.6V.

76. The method of operating a mask programmable NOR ROM device of claim 72 wherein the bit line connected to an unselected plurality of serially connected ROM transistors is set to a voltage level of approximately ground reference voltage level.

77. The method of operating a mask programmable NOR ROM device of claim 76 wherein if The method of operating a mask programmable NOR ROM device is not selected for reading, the control gates of all the ROM transistors of the plurality of serially connected ROM transistors is set to the ground reference voltage level to turn off the ROM transistors to block leakage current through the unselected plurality of serially connected ROM transistors.
